(19) United States
(12) Patent Application Publication
(10) Pub. No.: US 2008/0129562 A1
(43) Pub. Date: Jun. 5, 2008

(54) Semiconductor Integrated Circuit Having Jitter Measuring Function

(76) Inventors: Keisuke Nakahira, Osaka (JP); Seiji Watanabe, Kyoto (JP); Tetsuo Arakawa, Osaka (JP); Akifumi Takeya, Osaka (JP); Takashi Oka, Osaka (JP)

Correspondence Address: MCDERMOTT WILL & EMERY LLP, 600 13TH STREET, NW, WASHINGTON, DC, 20005-3096, US

(21) Appl. No.: 11/661,404

(22) PCT Filed: Apr. 13, 2005
(86) PCT No.: PCT/JP05/07164

§ 371 Date: Feb. 28, 2007

(30) Foreign Application Priority Data
Aug. 30, 2004 (JP) 2004-250224

(51) Int. Cl. H03M 1/06

(52) U.S. Cl. 341/118

(57) ABSTRACT

A semiconductor integrated circuit having jitter measuring function includes a slicer (11), a T/V converter (12), an A/D converter (13), a processor (14), a multiplexer (15), and a correction section (16). The slicer (11) binarizes an input signal to generate a data signal. The T/V converter (12) outputs a voltage corresponding to the data length of an input signal. The multiplexer (15) selects the data signal or a reference signal as the input signal to the T/V converter (12). The A/D converter (13) converts the output voltage of the TN converter (12) to digital data. The processor (14) measures jitter in the input signal to the T/V converter (12) in accordance with the digital data. The correction section (16) compares the output voltage of the T/V converter (12) produced where the reference signal has been selected by the multiplexer (15) with a predetermined voltage, and corrects the output characteristics of the T/V converter (12) according to the comparison results.

### TECHNICAL FIELD

The present invention relates to semiconductor integrated circuits, and more particularly relates to a semiconductor integrated circuit having the function of measuring jitter in an EFM (eight to fourteen modulation) signal used in a CD (compact disc) device and the like.

### BACKGROUND ART

In optical disk devices, jitter in a data signal read from an optical disk is generally measured by the following two methods. One is a data-to-clock jitter measurement method used in DVD (digital versatile disc) devices and the like, and the other is a jitter measurement method called a 3 T or 22 T method, which is used in CD devices and the like.

A data-to-clock measurement circuit is incorporated into an LSI (large scale integrated circuit) for the learning function of the LSI. In DVD devices, jitter measurement for delivery inspection can thus be performed using the data-to-clock measurement circuit. In a CD device, a circuit for measuring jitter is not incorporated into an LSI. This is because, in the first place, jitter measuring function is unnecessary for LSIs. Jitter measurement in delivery inspection of a CD device is performed using a jitter meter which is commercially manufactured and sold as a measuring instrument.

FIG. 5 illustrates the structure of a jitter meter. A slicer 11 binarizes an EFM signal as an input signal to generate a data signal. The EFM signal has been created so that the probability of generation of high level and the probability of generation of low level are equal to each other. In the slicer 11, duty feedback is performed so that the average length of the data signal's high-level period and the average length of the data signal's low-level period are equal to each other so as to reduce the influence of the asymmetry of the input signal. A T/V converter 12 measures the data length of the data signal and outputs a voltage corresponding to the data length. Specifically, the T/V converter 12 measures, as the data length, the positive or negative pulse width of the data signal. During the measurement, the T/V converter 12 charges the sawtooth waveform, and at the time when the measurement is complete, the T/V converter 12 outputs the charged voltage. The T/V converter 12 has the function of selecting a data signal having a specific data length. An A/D converter 13 converts the output voltage of the T/V converter 12 to digital data. A processor 14 receives the digital data and calculates the average value, variance, standard deviation, etc. of jitter in the data signal. In this way, the jitter of the EMF signal is measured and the statistics thereof is taken (see Non-Patent Document 1, for example).

### Non-Patent Document 1: Digital Processing Jitter Meter Instruction Manual, LEADER ELECTRONICS CORP.

### DISCLOSURE OF THE INVENTION

### Problem that the Invention Intends to Solve

However, in the conventional method that uses jitter meters to perform delivery inspection of CD devices, a jitter meter must be provided for each fabrication line, which causes the delivery inspection cost to increase. It is thus required that the LSI itself measure jitter without using a jitter meter. Nevertheless, if the function of the above-described jitter meter is just incorporated into LSIs without modification, jitter measurement results vary from LSI to LSI due to fabrication variations in the LSIs, and it is thus difficult to use the measurement results in the delivery inspection.

In view of the above problem, it is an object of the present invention to realize semiconductor integrated circuits capable of highly precise jitter measurement in which variation due to variation among the individual circuits does not occur.

### Means for Solving the Problem

In order to solve the above-described problem, an inventive semiconductor integrated circuit includes: a slicer for binarizing an input signal to generate a data signal; a T/V converter for outputting a voltage corresponding to the data length of an input signal; a multiplexer for selecting either the data signal or a reference signal as the input signal to the T/V converter; an A/D converter for converting the output voltage of the T/V converter to digital data; a processor for measuring jitter in the input signal to the T/V converter in accordance with the digital data; and a correction section for comparing a predetermined voltage with the output voltage of the T/V converter produced where the reference signal has been selected by the multiplexer, and correcting output characteristics of the T/V converter in accordance with results of the comparison.

In the inventive semiconductor integrated circuit, the reference signal is selected by the multiplexer as the input signal to the T/V converter, and the correction section makes a comparison between the predetermined voltage and the output voltage of the TN converter produced as a result of the input of the reference signal. Based on the comparison results, the output characteristics of the T/V converter are corrected. Consequently, highly accurate jitter measurement, in which variation due to variation among the individual circuits does not occur, is realized.

The correction section preferably adjusts a gain and offset of the T/V converter.

The processor preferably measures the jitter in the input signal to the TN converter in accordance with the digital data that falls within a predetermined range.

The processor preferably calculates an average value of the data lengths of input signals to the T/V converter in accordance with the digital data to calculate a deviation of the average value from an ideal value, and the semiconductor integrated circuit preferably includes a slice level correction section for correcting the slice level of the slicer in accordance with the deviation calculated by the processor.

The semiconductor integrated circuit preferably includes an amplifier for amplifying the output voltage of the T/V converter, wherein the A/D converter preferably converts the voltage amplified by the amplifier to the digital data.

The processor preferably calculates a deviation of a gain of the T/V converter from an ideal gain in accordance with first digital data and second digital data which are output from the A/D converter, and corrects the digital data in accordance with the calculated deviation, the first digital data being output where a first reference signal having a first data length has been selected by the multiplexer, the second digital data being output where a second reference signal having a second data length has been selected by the multiplexer.

The processor preferably subtracts a variance of the jitter obtained where the reference signal has been selected as the input signal to the T/V converter from a variance of the jitter obtained where the data signal has been selected as the input signal to the T/V converter.

Function in the semiconductor integrated circuit other than the function of jitter measurement is preferably shared by at least one of the slicer, the A/D converter, and the processor.

### EFFECTS OF THE INVENTION

As described above, according to the present invention, the semiconductor integrated circuits having the jitter measuring function achieve highly precise jitter measurement in which variation caused by variation among the individual circuits does not occur. Therefore, jitter meters do not have to be used any more in delivery inspection, and the delivery inspection cost and hence the fabrication cost of the semiconductor integrated circuits are reduced.

### BRIEF DESCRIPTION OF DRAWINGS

FIG. 1 illustrates a function block in a semiconductor integrated circuit according to a first embodiment of the present invention.

FIG. 2 illustrates a function block in a semiconductor integrated circuit according to a second embodiment of the present invention.

FIG. 3 illustrates a function block in a semiconductor integrated circuit according to a third embodiment of the present invention.

FIG. 4 illustrates an example in which a multiplexer is disposed in a different position.

FIG. 5 illustrates the structure of a jitter meter.

### EXPLANATION OF THE REFERENCE CHARACTERS

1 Slicer
12 T/V converter
13 A/D converter
14 Processor
15 Multiplexer
16 Correction section
17 Slice level correction section
18 Amplifier

### BEST MODE FOR CARRYING OUT THE INVENTION

Hereinafter, embodiments of the present invention will be described with reference to the accompanying drawings.

### First Embodiment

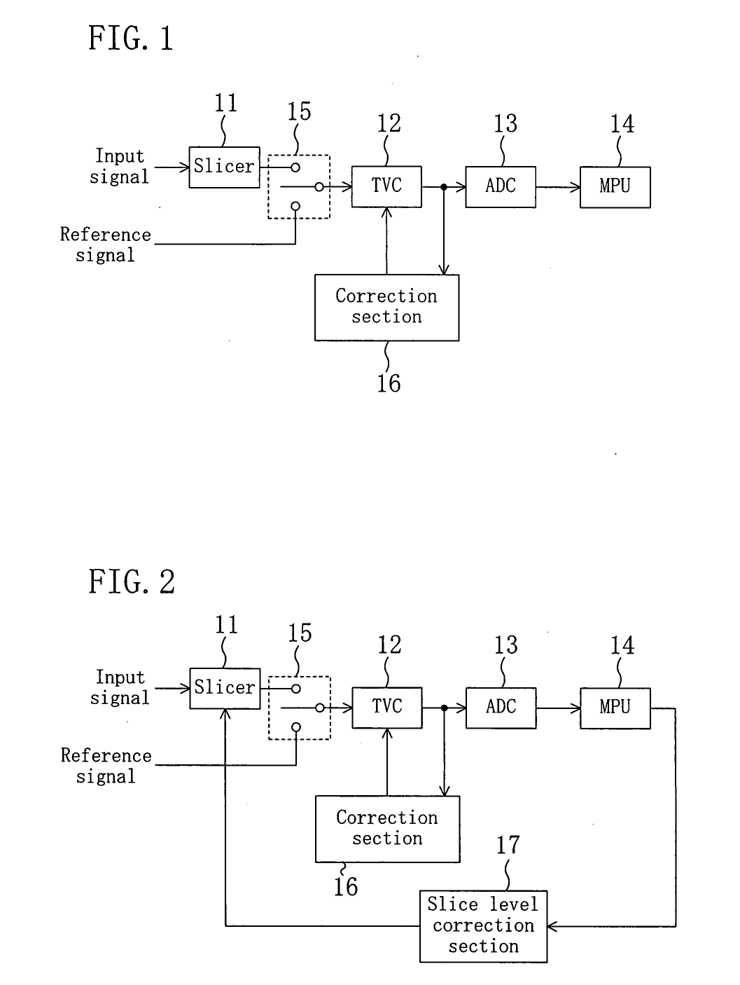

FIG. 1 illustrates a function block in a semiconductor integrated circuit according to a first embodiment of the present invention. The semiconductor integrated circuit of this embodiment includes a slicer 11, a T/V converter 12, an A/D converter 13, a processor 14, a multiplexer 15, and a correction section 16. The slicer 11, the T/V converter 12, the A/D converter 13, and the processor 14 operate as described above. The multiplexer 15 selects a data signal output from the slicer 11 or a reference signal as an input signal to the T/V converter 12. The correction section 16 corrects the output characteristics of the T/V converter 12. In a case where the output of the slicer 11 has been selected by the multiplexer 15, typical jitter measurement is performed as in conventional cases. Where the reference signal has been selected, the output characteristics of the T/V converter 12 are corrected in the following manner.

Since the T/V converter 12 has variation caused during the fabrication of the LSI, the gain of the T/V converter 12, which is defined by a change in conversion voltage with respect to a change in the length of input data, varies from LSI to LSI. In addition, an absolute voltage that is output when data having a proper data length is input, that is, the offset, also varies from LSI to LSI. When the processor 14 performs arithmetic processing for obtaining a standard deviation or the like, the former variation becomes variation in the standard deviation itself, and thus directly and adversely affects the jitter measurement results. The latter variation becomes variation in the center voltage in the distribution of the voltage obtained by the T/V conversion. If the center voltage varies greatly, the output voltage of the T/V converter 12 falls outside the input range of the A/D converter 13, which may lead to erroneous jitter measurement results. Therefore, the correction section 16 corrects the output characteristics of the T/V converter 12 to reduce variation among the LSIs.

Specifically, the output characteristics of the T/V converter 12 are corrected as follows. First, the multiplexer 15 inputs the reference signal to the T/V converter 12. The reference signal is a jitter-free data signal having a predetermined data length, that is, a proper data signal. The reference signal may be externally provided, or may be generated inside the LSI. The correction section 16 compares a predetermined voltage with the output voltage of the T/V converter 12, to which the reference signal has been input, and gives feedback to the T/V converter 12 according to the comparison results. More specifically, the correction section 16 adjusts the gain of the T/V converter 12 so that the output voltage of the T/V converter 12 is equal to the predetermined voltage. Consequently, variation in the gain of the T/V converter 12 from LSI to LSI is reduced.

Furthermore, the correction section 16 performs offset adjustments so that the output voltage of the T/V converter 12 is in the vicinity of the center of the input range of the A/D converter 13. As a result, the output voltage of the T/V converter 12 falls within the input range of the A/D converter 13, whereby accurate jitter measurement results are obtained.

As already described, the T/V converter 12 has the function of selecting a data signal having a specific data length. Nevertheless, when jitter is relatively large, a distinction between the specific data length and the other lengths cannot be made clearly, and thus a data signal whose data length is other than the specific data length may be selected. For example, when the specific data length is 3 T, a data signal having a data length of 2 T or 4 T may be selected. If such a data signal having a data length other than the specific data length is contained in the output of the T/V converter 12, the reliability of the final jitter measurement results decreases. Thus, limitations are placed on digital data to be processed by the processor 14, so that the processor 14 only processes data within the predetermined range. Specifically, in the case where the specific data length is 3 T, the limitations are placed so that only digital data whose data length is close to 3 T, e.g., in the range from 2.5 T to 3.5 T, is processed. Then, the accuracy of jitter measurement results is increased further.

As the precision of the correction by the correction section 16 is improved, variation in the output characteristics of the T/V converter 12 from LSI to LSI is reduced. However, the improvement in the precision of the correction requires the circuit size of the correction section 16 to be increased. Furthermore, the predetermined voltage that is compared with the output voltage of the T/V converter 12, and the offset of a comparator (not shown) which performs actual comparison operation vary from LSI to LSI. Thus, the occurrence of some variation in jitter measurement from T/V converter 12 to T/V converter 12 is unavoidable. It is therefore desired that the correction section 16 make coarse adjustments, and the processor 14 make fine adjustments, so that the jitter measurement precision is improved.

To be specific, the processor 14 receives digital data V1 output when a first reference signal whose data length is 3 T is supplied to the T/V converter 12, and digital data V2 output when a second reference signal whose data length is 2.5 T is supplied to the T/V converter 12. The gain of the T/V converter 12 at this time is expressed by (V1−V2)/(3 T−2.5 T). Assume that the ideal value of the digital data related to the first reference signal is V10, and the ideal value of the digital data related to the second reference signal is V20. In this case, in the processor 14, input digital data may be multiplied by (V10−V20)/(V1−V2). Then, the gain error in the T/V converter 12 is corrected by the processor 14, whereby the accuracy of the jitter measurement results is increased further.

In an LSI incorporating jitter measuring function, noise from other circuits in the LSI is sometimes applied to the T/V converter 12 and the A/D converter 13. Such noise applied from the other circuits is measured as jitter to cause an error in the jitter measurement results. The following measures are thus preferably taken. The processor 14 calculates the variance of jitter observed with the reference signal being input. Since the reference signal does not contain jitter, the variance obtained at this time is mainly due to the noise. The processor 14 stores this variance and subtracts the stored variance from the variance of jitter observed by the input of an ordinary data signal, whereby the jitter measurement error caused by the noise from the other circuits in the LSI is cancelled.

As described above, according to this embodiment, in the LSIs having the jitter measuring function, fabrication variations among the LSIs are reduced. As a result, accurate jitter measurement is realized irrespective of variations among the individual LSIs.

It should be noted that the correction section 16 may be configured as hardware or may be performed as software processing by using a DSP (digital signal processor) or the like. Also, each of the slicer 11, the A/D converter 13, and the processor 14 may be shared with other function in the LSI or the like by using a time sharing system, whereby the layout area of the LSI is reduced.

### Second Embodiment

FIG. 2 illustrates a function block in a semiconductor integrated circuit according to a second embodiment of the present invention. The semiconductor integrated circuit of this embodiment has a structure obtained by adding a slice level correction section 17 to the semiconductor integrated circuit of the first embodiment (see FIG. 1).

In some of the EFM signals, which are input signals having a specific data length, the specific data length deviates from a proper data length. A processor 14 detects jitter in input signals by using a certain detection window. A signal whose data length deviates falls outside the detection window and the jitter in that signal is not measured. That is, the jitter of the jitter-measurement-target data signal is not measured, which might result in erroneous jitter measurement results. Therefore, the slice level of the slicer 11 is corrected by the slice level correction section 17 to reduce the deviation of the data length of the data signal.

Specifically, the processor 14 calculates the average value of each of the data lengths in the input signal and outputs a deviation of the average value from its ideal value. Based on this deviation, the slice level correction section 17 adjusts the slice level of the slicer 11. To be more specific, the slice level correction section 17 gives feedback to the slicer 11 until the deviation disappears.

As described above, according to this embodiment, in the semiconductor integrated circuit having the jitter measuring function, adjustments are performed so that the average value of the distribution of input signal data lengths is its ideal value. As a result, precise jitter measurement is realized.

### Third Embodiment

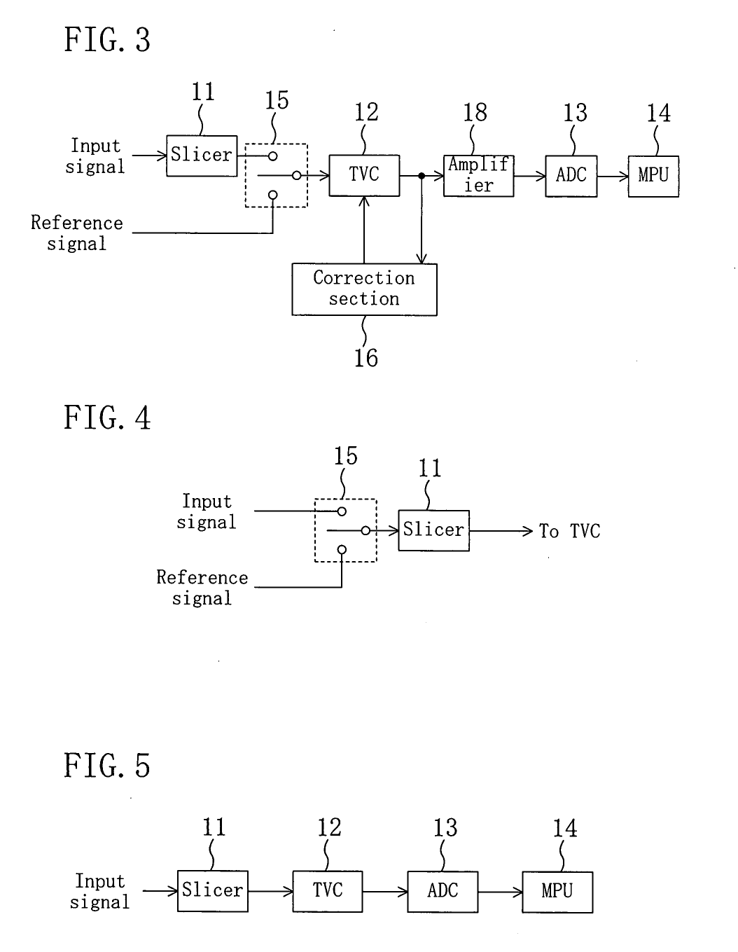

FIG. 3 illustrates a function block in a semiconductor integrated circuit according to a third embodiment of the present invention. The semiconductor integrated circuit of this embodiment has a structure obtained by adding an amplifier 18 to the semiconductor integrated circuit of the first embodiment (see FIG. 1).

In the present invention, a jitter to be measured is defined as a data-length-independent absolute value, more specifically, as a value obtained by dividing a deviation of an observed data length from its ideal data length by a predetermined value (a reference data length). According to this definition, a jitter of Ins in a data signal whose data length is 3 T is the same in magnitude as a jitter of Ins in a data signal whose data length is 11 T, for example.

In the 11 T method, as compared with the 3 T method, an integration time for integrating a sawtooth waveform in a T/V converter 12 is longer, and hence the output voltage is larger. In the 11 T method, therefore, the gain of the T/V converter 12 must be lowered as compared with the 3 T method, so that the output voltage of the T/V converter 12 falls within the input range of the A/D converter 13. However, the lowered gain causes reduction in jitter, such that jitter that is different in magnitude from the actual jitter is measured, resulting in decrease in the jitter measurement accuracy. The processor 14 can compensate for the jitter reduction, but in order to allow the processor 14 to make the compensation, the A/D converter 13 is required to output highly accurate digital data. Improving the accuracy of the A/D converter 13, however, leads to increase in costs and is thus not desirable. As shown in FIG. 3, therefore, the amplifier 18 is provided between the T/V converter 12 and the A/D converter 13.

The amplifier 18 amplifies the output voltage of the T/V converter 12, and the A/D converter 13 outputs digital data corresponding to the amplified voltage. That is, the jitter reduced by the T/V converter 12 is amplified to the original magnitude by the amplifier 18, and then the amplified voltage is supplied to the A/D converter 13. Consequently, in the semiconductor integrated circuit having the jitter measuring function, the precision of the jitter measurement by the 11 T method is increased.

In the above-described embodiments of the present invention, as shown in FIG. 4, the multiplexer 15 may select either the input signal or the reference signal, and the selected signal may be binarized by the slicer 11.

### INDUSTRIAL APPLICABILITY

The semiconductor integrated circuits according to the present invention have the function of performing highly accurate jitter measurement in which variation caused by variation among the individual circuits does not occur, and are thus applicable to LSIs for writable CD devices.

1-8. (canceled)

9. A semiconductor integrated circuit comprising:
a slicer for binarizing an input signal to generate a data signal;
a T/V converter for outputting a voltage corresponding to the data length of an input signal;
a multiplexer for selecting either the data signal or a reference signal as the input signal to the T/V converter;
an A/D converter for converting the output voltage of the T/V converter to digital data;
a processor for calculating an average value of the data lengths of input signals to the T/V converter in accordance with the digital data to calculate a deviation of the average value from an ideal value;
a correction section for comparing a predetermined voltage with the output voltage of the T/V converter produced where the reference signal has been selected by the multiplexer, and correcting output characteristics of the T/V converter in accordance with results of the comparison; and
a slice level correction section for correcting the slice level of the slicer in accordance with the deviation calculated by the processor.

10. A semiconductor integrated circuit comprising:
a slicer for binarizing an input signal to generate a data signal;
a T/V converter for outputting a voltage corresponding to the data length of an input signal;
a multiplexer for selecting either the data signal or a reference signal as the input signal to the T/V converter;
an A/D converter for converting the output voltage of the T/V converter to digital data;
a processor for measuring jitter in the input signal to the T/V converter in accordance with the digital data; and
a correction section for comparing a predetermined voltage with the output voltage of the T/V converter produced where the reference signal has been selected by the multiplexer, and correcting output characteristics of the T/V converter in accordance with results of the comparison,
wherein the processor calculates a deviation of a gain of the T/V converter from an ideal gain in accordance with first digital data and second digital data which are output from the A/D converter, and corrects the digital data in accordance with the calculated deviation, the first digital data being output where a first reference signal having a first data length has been selected by the multiplexer, the second digital data being output where a second reference signal having a second data length has been selected by the multiplexer.

11. A semiconductor integrated circuit comprising:
a slicer for binarizing an input signal to generate a data signal;
a T/V converter for outputting a voltage corresponding to the data length of an input signal;
a multiplexer for selecting either the data signal or a reference signal as the input signal to the T/V converter;
an A/D converter for converting the output voltage of the T/V converter to digital data;
a processor for measuring jitter in the input signal to the T/V converter in accordance with the digital data; and
a correction section for comparing a predetermined voltage with the output voltage of the T/V converter produced where the reference signal has been selected by the multiplexer, and correcting output characteristics of the T/V converter in accordance with results of the comparison,
wherein the processor subtracts a variance of the jitter obtained where the reference signal has been selected as the input signal to the T/V converter from a variance of the jitter obtained where the data signal has been selected as the input signal to the T/V converter.
